(19) United States
(12) Patent Application Publication
(10) Pub. No.: US 2026/0007058 A1
(43) Pub. Date: Jan. 1, 2026

(54) WINDOW, DISPLAY DEVICE, AND ELECTRONIC DEVICE

(71) Applicant: Samsung Display Co., Ltd., Yongin-si (KR)

(72) Inventor: JONGHWAN CHO, Yongin-si (KR)

(21) Appl. No.: 19/197,850

(22) Filed: May 2, 2025

(30) Foreign Application Priority Data
Jun. 26, 2024 (KR) 10-2024-0083258

(51) Int. Cl. H10K 59/80; C03C 17/34

(52) U.S. Cl. CPC H10K 59/8792; C03C 17/3452; H10K 59/873; C03C 2217/228; C03C 2217/285; C03C 2217/73

(57) ABSTRACT

A window according to one or more embodiments of the disclosure includes a base layer, a first layer on the base layer, a second layer below the base layer, a third layer on the first layer, and a fourth layer on the third layer, each of the first layer and the second layer including a magnesium oxide (e.g., MgO), a magnesium fluoride (e.g., MgF₂), and an yttrium oxyfluoride (e.g., YOF). In addition, a display device and an electronic device including the window are also provided.

### CROSS-REFERENCE TO RELATED APPLICATION

The present application claims priority to and the benefit of Korean Patent Application No. 10-2024-0083258, filed on Jun. 26, 2024, in the Korean Intellectual Property Office, the entire content of which is incorporated herein by reference.

### BACKGROUND

### 1. Field

One or more embodiments of the present disclosure relate to a window and a display device including the same, for example, one or more embodiments of the present disclosure relate to a window having low reflectance and enhanced (e.g., excellent or suitable) mechanical characteristics, and a display device including the window.

### 2. Description of the Related Art

Display devices are extensively used for one or more suitable multimedia devices such as televisions, mobile phones, tablet computers, and/or game consoles, to provide image information for users. Recently, there are significant developments in flexible display devices that have one or more suitable shapes capable of being folded or bent. The flexible display devices may be changed in shape, for example, being folded, rolled, or bent, and thus have desirable portable characteristics.

Flexible display devices may include display panels and windows capable of being folded or bent. However, the windows of the flexible display devices may be deformed due to folding or bending operations, or may be easily damaged due to external impacts.

### SUMMARY

One or more aspects of embodiments of the present disclosure are directed toward a window that has low reflectance and enhanced (e.g., excellent or suitable) durability.

One or more aspect of embodiments of the present disclosure are directed toward a display device with improved display efficiency and maintained low reflectance by including the window.

Additional aspects will be set forth in part in the description which follows and, in part, will be apparent from the description, or may be learned by practice of the presented embodiments.

According to one or more embodiments of the present disclosure, a window includes a base layer, a first layer on (e.g., arranged on) the base layer, a second layer below (e.g., arranged below) the base layer, a third layer on (e.g., arranged on) the first layer, and a fourth layer on (e.g., arranged on) the third layer, each of the first layer and the second layer including a magnesium oxide (e.g., MgO), a magnesium fluoride (e.g., MgF₂), and an yttrium oxyfluoride (e.g., YOF).

In one or more embodiments, each of the first layer and the second layer may have a thickness of about 65 nanometers (nm) to about 85 nm.

In one or more embodiments, the first layer may be in contact with a top surface of the base layer, and the second layer may be in contact with a bottom surface of the base layer.

In one or more embodiments, a refractive index of each of the first layer and the second layer at a wavelength of about 550 nm may be about 1.38 to about 1.42, a refractive index of the third layer at the wavelength of about 550 nm may be about 1.46 to about 1.50, and a refractive index of the fourth layer at the wavelength of about 550 nm may be about 1.30 to about 1.35.

In one or more embodiments, each of the first layer and the second layer may include a solid solution in which the magnesium oxide, the magnesium fluoride, and the yttrium oxyfluoride are mixed.

In one or more embodiments, at least one of the first layer or the second layer may further include SiₓO_{y}Mg_{z}AlᵤNᵥ. In SiₓO_{y}Mg_{z}AlᵤNᵥ, x, y, z, u, and v may each independently be a value of 0 to 1, and satisfy x+y+z+u+v≤1.

In one or more embodiments, the third layer may include silicon oxide (e.g., SiO₂) and aluminum oxide (e.g., Al₂O₃).

In one or more embodiments, the third layer may include Si₉Al₂O₁₀.

In one or more embodiments, the fourth layer may include a fluorine-containing polymer.

In one or more embodiments, a reflectance of a top surface of the fourth layer at a wavelength of about 550 nm may be about 4.2% or less.

In one or more embodiments, the window may further include a fifth layer between (e.g., arranged between) the base layer and the first layer and including a hard coating agent, and the first layer may be directly on (e.g., arranged on) the hard coating agent.

In one or more embodiments, the third layer may have a thickness of about 5 nm to about 30 nm, and the fourth layer may have a thickness of about 5 nm to about 40 nm.

In one or more embodiments, the base layer may be divided into a transmission area and a bezel area on a plane, and the window may further include a light blocking layer below (e.g., arranged below) the base layer and overlapping the bezel area.

In one or more embodiments, the base layer may include a top surface adjacent to the first layer and a bottom surface opposing the top surface in a thickness direction. Each of the light blocking layer and the second layer may be on (e.g., arranged on) the bottom surface of the base layer, and the light blocking layer may not overlap the second layer in a plan view (e.g., on a plane).

In one or more embodiments, the second layer may overlap the transmission area and the bezel area, and the light blocking layer may be on (e.g., arranged on) a bottom surface of the second layer.

In one or more embodiments, the light blocking layer may include a first light blocking layer below (e.g., arranged below) the base layer, and a second light blocking layer below (e.g., arranged below) the first light blocking layer, and each of the first light blocking layer and the second light blocking layer may independently include at least one of an acrylic urethane-based compound, an epoxy-based compound, a polyester-based compound, or an epoxy ester-based compound.

According to one or more embodiments of the present disclosure, a display device includes a display module and a window on (e.g., arranged on) the display module, and the window includes a base layer, a first layer on (e.g., arranged on) the base layer, a second layer below (e.g., arranged below) the base layer, a third layer on (e.g., arranged on) the first layer, and a fourth layer on (e.g., arranged on) the third layer, each of the first layer and the second layer including a magnesium oxide (e.g., MgO), a magnesium fluoride (e.g., MgF₂), and an yttrium oxyfluoride (e.g., YOF).

In one or more embodiments, the display module may include a base substrate, a circuit layer on (e.g., arranged on) the base substrate, a light emitting element layer on (e.g., arranged on) the circuit layer, an encapsulation layer on (e.g., arranged on) the light emitting element layer, and an anti-reflective layer on (e.g., arranged on) the encapsulation layer. The anti-reflective layer may include a division layer in which a plurality of division openings overlapping a plurality of light emitting elements, respectively, are defined, and a plurality of color filters arranged to correspond to the plurality of division openings, respectively.

In one or more embodiments, the base layer may be spaced and/or apart (e.g., spaced apart or separated) from the display module with the second layer therebetween.

In one or more embodiments, a top surface of the fourth layer may define an (e.g., the) outermost surface of the window.

According to one or more embodiments of the present disclosure, an electronic device includes a display module, a window on (e.g., arranged on) the display module, and a housing that is arranged below the display module and coupled with the window to accommodate the display module, and the window includes a base layer, a first layer on (e.g., arranged on) the base layer, a second layer below (e.g., arranged below) the base layer, a third layer on (e.g., arranged on) the first layer, and a fourth layer on (e.g., arranged on) the third layer, each of the first layer and the second layer including a magnesium oxide (e.g., MgO), a magnesium fluoride (e.g., MgF₂), and an yttrium oxyfluoride (e.g., YOF).

### BRIEF DESCRIPTION OF DRAWINGS

The accompanying drawings are included to provide a further understanding of the disclosure, and are incorporated in and constitute a part of this disclosure. The drawings illustrate embodiments of the present disclosure and, together with the description, serve to explain principles of the disclosure. Above and/or other aspects of the present disclosure should become apparent and appreciated from the following description of embodiments taken in conjunction with the accompanying drawings. In the drawings:

FIG. 1A is an assembled perspective view of a display device according to one or more embodiments of the disclosure;

FIG. 1B is an exploded perspective view of a display device according to one or more embodiments of the disclosure;

FIG. 2 is a cross-sectional view of a display device according to one or more embodiments of the disclosure;

FIG. 3 is a cross-sectional view illustrating a portion of a display module according to one or more embodiments of the disclosure;

FIGS. 4A-4D are each a cross-sectional view of a window according to one or more embodiments of the disclosure; and

FIG. 5A and FIG. 5B are each a cross-sectional view illustrating some components of a window according to one or more embodiments of the disclosure.

FIG. 6 is a block diagram of an electronic device according to one or more embodiments of the disclosure.

FIG. 7 illustrates schematic views of electronic devices according to one or more embodiments of the disclosure.

### DETAILED DESCRIPTION

Embodiments of the present disclosure may be modified and practiced in many alternate forms, and thus example embodiments will be exemplified in the drawings and described in more detail. It should be understood, however, that it is not intended to limit the disclosure to the particular forms disclosed, but rather, is intended to cover all modifications, equivalents, and alternatives falling within the spirit and scope of the disclosure.

In this disclosure, it will be understood that if (e.g., when) an element (or a region, a layer, a section, and/or the like) is referred to as being “on”, “connected to”, or “coupled to” another element, it may be directly arranged on, connected or coupled to the other element, or a third element may be arranged therebetween.

In the present disclosure, like reference numbers or symbols refer to like elements throughout, and duplicative descriptions thereof may not be provided for conciseness. In addition, in the drawings, the thickness, the ratio, and the dimension of elements may be exaggerated for effective description of the technical contents. The term “and/or” or “or” may include one or more combinations which may be defined by relevant elements.

It will be understood that, although the terms “first,” “second,” and/or the like may be used herein to describe one or more elements, these elements should not be limited by these terms. These terms are only used to distinguish one element from another element. For example, a first element could be termed a second element without departing from the teachings of the disclosure, and similarly, a second element could be termed a first element. As used herein, the singular forms are intended to include the plural forms as well, unless the context clearly indicates otherwise. For example, the singular forms “a,” “an,” and “the” are intended to include the plural forms as well, unless the context clearly indicates otherwise. Further, the use of “may” when describing embodiments of the present disclosure refers to “one or more embodiments of the present disclosure.”

In addition, the terms, such as “below”, “beneath”, “on”, and “above”, are used for explaining the relation of elements shown in the drawings. The terms are relative concept and are explained based on the direction shown in the drawing.

It will be further understood that the terms such as “comprise(s)/comprising”, “include(s)/including”, or “have (has)/having”, if (e.g., when) used herein, specify the presence of stated features, numerals, steps, operations, elements, parts, or any combination thereof, but do not preclude the presence or addition of one or more other features, numerals, steps, operations, elements, parts, or combinations thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the wording “being directly arranged (on)” or “being directly on” may refer to that there is no additional layer, film, region, plate and/or the like between a part such as a layer, a film, a region, a plate, and/or the like and another part. For example, “being directly arranged (on)” or “being directly on” may refer to that two layers or two members are arranged with no additional member such as an adhesive member therebetween.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the disclosure will be described in more detail with reference to the accompanying drawings.

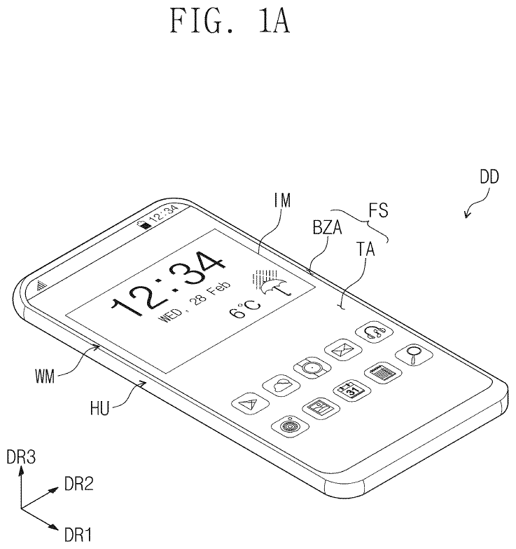

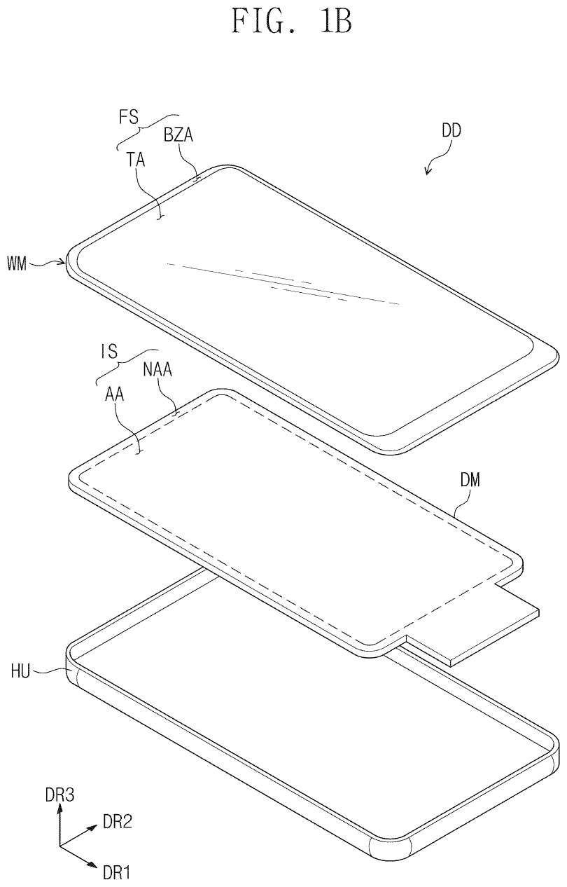

FIG. 1A is an assembled perspective view of a display device according to one or more embodiments of the disclosure. FIG. 1B is an exploded perspective view of a display device according to one or more embodiments of the disclosure. Referring to FIG. 1A, a display device DD may be a device that is activated

in response to an electrical signal. The display device DD may display an image IM and detect an external input. The display device DD may include one or more suitable embodiments. For examples, the display device DD may include a tablet computer, a notebook computer, a computer, a smart television, a smartphone, and/or the like. Here, a smartphone is illustrated as an example of the display device DD.

The display device DD may display the image IM toward a third direction DR3 on a display surface FS parallel to each of a first direction DR1 and a second direction DR2 (e.g., parallel to a plane defined by the first direction DR1 and the second direction DR2). The display surface FS on which the image IM is displayed may correspond to a front surface of the display device DD, and may correspond to a front surface FS of a window WM. Hereinafter, the display surface and the front surface of the display device DD, and the front surface of the window WM are designated by the like reference symbol. The image IM may include not only a dynamic image but also a still image. FIG. 1A illustrates a clock and a plurality of icons as an example of the image IM.

In these embodiments, a front surface (or top surface) and a rear surface (or bottom surface) of each of members are defined based on a direction in which the image IM is displayed. The front surface and the rear surface may oppose each other in the third direction DR3, and a normal direction to each of the front surface and the rear surface may be parallel to the third direction DR3. In one or more embodiments, a spaced distance between the front surface and the rear surface in the third direction DR3, may correspond to a thickness of a display panel 100 in the third direction DR3. In one or more embodiments, directions indicated by the first to third directions DR1, DR3, and DR3 are relative concepts and may be changed to other directions. Hereinafter the first to third directions are directions indicated by the first to third directions DR1, DR2, and DR3, and designated by the same reference symbols, respectively. In addition, the phrase “on a plane” or “in a plan view” used herein may refer to being in a state if (e.g., when) viewed in the third direction DR3. The phrase “in a cross-sectional view” used herein may refer to being in a state when viewed along a plane that is perpendicular to the third direction DR3.

The display device DD according to one or more embodiments of the disclosure may detect a user's external input applied from the outside. The user's external input may include one or more suitable types (kinds) of external inputs such as part of the user's body, light, heat, or pressure. The user's external input may be provided in one or more suitable types (kinds), and the display device DD may also detect the user's external input applied to a side surface or a rear surface of the display device DD according to a structure of the display device DD, but embodiments of the present disclosure are not limited thereto.

As illustrated in FIG. 1A and FIG. 1B, in one or more embodiments, the display device DD may include the window WM, a display module DM, and an outer case HU. In one or more embodiments, the window WM and the outer case HU are coupled to constitute an outer appearance of the display device DD. In one or more embodiments, the outer case HU, the display module DM, and the window WM may be stacked in sequence in the third direction DR3.

The window WM may include an optically transparent material. The window WM may include an insulation panel. For example, in one or more embodiments, the window WM may include glass, plastic, and/or a (e.g., any suitable) combination thereof.

As described above, the front surface FS of the window WM defines the front surface of the display device DD. A transmission area TA may be an optically transparent area. For example, in one or more embodiments, the transmission area TA may be an area having a visible light transmittance of about 90% or more.

A bezel area BZA may be an area having a relatively low light transmittance if (e.g., when) compared to the transmission area TA. The bezel area BZA defines a shape of the transmission area TA. The bezel area BZA may be adjacent to the transmission area TA and be around (e.g., surround) the transmission area TA.

The bezel area BZA may have a set or predetermined color. The bezel area BZA may cover a peripheral area NAA of the display module DM to prevent or reduce the peripheral area NAA from being visible from the outside. However, this is illustrated as an example, for example, the bezel area BZA may not be provided in the window WM according to one or more embodiments of the disclosure.

The display module DM may display the image IM and detect an external input. The image IM may be displayed on a front surface IS of the display module DM. The front surface IS of the display module DM includes an active area AA and the peripheral area NAA. The active area AA may be an area that is activated in response to an electrical signal.

In one or more embodiments, the active area AA may be an area on which the image IM is displayed, and also an area through which the external input is detected. The transmission area TA overlaps at least the active area AA. For example, the transmission area TA may overlap the front surface IS or at least a portion of the active area AA. Accordingly, a user may see the image IM through the transmission area TA or provide an external input. However, this is illustrated as an example, and in the active area AA, an area on which the image IM is displayed, and an area through which an external input is detected may be separated from each other, and embodiments of the present disclosure are not limited thereto.

The peripheral area NAA may be an area that is covered by the bezel area BZA. The peripheral area NAA is adjacent to the active area AA. The peripheral area NAA may be around (e.g., surround) the active area AA. In one or more embodiments, a driving circuit, a driving line, and/or the like for driving the active area AA may be arranged in the peripheral area NAA.

The display module DM may include a display panel and a sensor layer. The image IM may be substantially displayed on the display panel, and the external input may be substantially detected through the sensor layer. By including both (e.g., simultaneously) the display panel and the sensor layer, the display module DM may display the image IM and also detect the external input. This will be described later in more detail.

The display device DD according to one or more embodiments may further include a driving circuit. The driving circuit may include a flexible circuit board and a main circuit board. The flexible circuit board may be electrically connected to the display module DM and the main circuit board. However, this is illustrated as an example. For example, the flexible circuit board according to one or more embodiments of the disclosure may not be connected to the main circuit board, and the flexible circuit board may be a rigid board.

The flexible circuit board may be connected to pads of the display module DM, which are arranged on the peripheral area NAA. The flexible circuit board may provide the display module DM with an electrical signal for driving the display module DM. The electrical signal may be generated by the flexible circuit board, or generated by the main circuit board. The main circuit board may include one or more suitable driving circuits for driving the display module DM, a connector for supplying power, and/or the like. In one or more embodiments, the main circuit board may be connected to the display module DM through the flexible circuit board.

As an example, FIG. 1B illustrates a state in which the display module DM is spread, but at least a portion of the display module DM may be bent. For example, in one or more embodiments, a portion of the display module DM may be bent toward a rear surface of the display module DM, and the portion bent toward the rear surface may be a portion to which the main circuit board is connected. Accordingly, the main circuit board may be assembled in a state of overlapping the rear surface of the display module DM.

The outer case HU is coupled to the window WM to define the outer appearance of the display device DD. The outer case HU provides a set or predetermined inner space. The display module DM may be accommodated in the inner space.

The outer case HU may include a material having relatively high rigidity. For examples, in one or more embodiments, the outer case HU may include glass, a plastic, or a metal, or may include a plurality of frames and/or plates made of a combination thereof. The outer case HU may stably protect components of the display device DD accommodated in the inner space from an external impact.

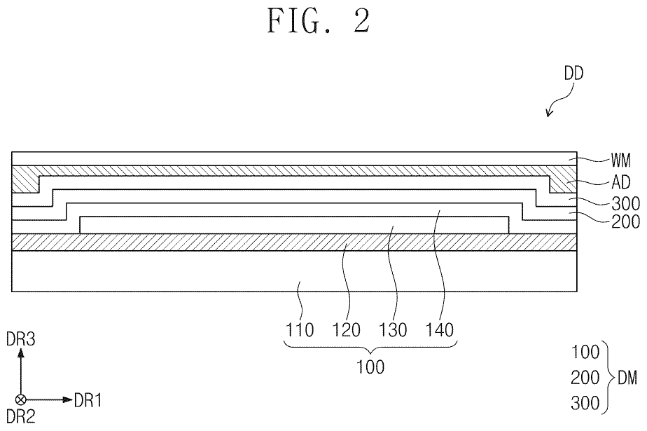

FIG. 2 is a cross-sectional view of a display device according to one or more embodiments of the disclosure.

Referring to FIG. 2, a display device DD may include a display module DM and a window WM. The display module DM and the window WM may be coupled to each other through an adhesive layer AD. In the display device DD according to one or more embodiments, the display module DM may include a display panel 100, a sensor layer 200, and an anti-reflective layer 300. Among the plurality of layers of the display module DM, the anti-reflective layer 300 may be coupled to the window WM through the adhesive layer AD.

The display panel 100 may be a component that substantially generates an image. The display panel 100 may be an emissive display panel. For example, the display panel 100 may be an organic light emitting display panel, an inorganic light emitting display panel, a micro light emitting diode (LED) display panel, or a nano LED display panel. In the disclosure, the display panel 100 may be referred to as a display layer.

The display panel 100 may include a base substrate 110, a circuit layer 120, a light emitting element layer 130, and an encapsulation layer 140.

The base substrate 110 may be a member that provides a base surface on which the circuit layer 120 is arranged. The base substrate 110 may be a rigid substrate, or a flexible substrate capable of being bent, folded, rolled, and/or the like. The base substrate 110 may be a glass substrate, a metal substrate, a polymer substrate, and/or the like. However, embodiments of the present disclosure are not limited thereto, and the base substrate 110 may be an inorganic layer, an organic layer, or a composite material layer.

The base substrate 110 may have a multilayer structure. For example, in one or more embodiments, the base substrate 110 may include a first synthetic resin layer, a multi-layered or single-layered inorganic layer, and a second synthetic resin layer arranged on the multi-layered or single-layered inorganic layer. In one or more embodiments, each of the first synthetic resin layer and the second synthetic resin layer may include a polyimide-based resin, but embodiments of the present disclosure are not particularly limited thereto.

The circuit layer 120 may be arranged on the base substrate 110. The circuit layer 120 may include an insulation layer, a semiconductor pattern, a conductive pattern, a signal line, and/or the like.

The light emitting element layer 130 may be arranged on the circuit layer 120. The light emitting element layer 130 may include a light emitting element. For example, the light emitting element may include an organic light emitting material, an inorganic light emitting material, an organic-inorganic light emitting material, a quantum dot, a quantum rod, a micro LED, or a nano LED.

The encapsulation layer 140 may be arranged on the light emitting element layer 130. The encapsulation layer 140 may protect the light emitting element layer 130 from moisture, oxygen, and/or foreign matter such as dust particles. In one or more embodiments, the encapsulation layer 140 may include at least one inorganic layer. In one or more embodiments, the encapsulation layer 140 may include a stack structure of inorganic layer/organic layer/inorganic layer.

The sensor layer 200 may be arranged on the display panel 100. The sensor layer 200 may detect an external input applied from the outside. The external input may be a user's input. The user's input may include one or more suitable types (kinds) of external inputs such as part of the user's body, light, heat, pen, or pressure.

In one or more embodiments, the sensor layer 200 may be formed on the display panel 100 through a continuous process. In these embodiments, the sensor layer 200 may be directly arranged on the display panel 100. Here, the phrase “being directly arranged on” may refer to that a third (e.g., any) component (or components) is (are) not arranged between the sensor layer 200 and the display panel 100. For example, a separate adhesive member may not be arranged between the sensor layer 200 and the display panel 100. For example, the sensor layer 200 can be formed directly on the display panel 100 through a continuous process in which no additional components, such as an adhesive member, are placed between the sensor layer 200 and the display panel 100.

The anti-reflective layer 300 may be directly arranged on the sensor layer 200. The anti-reflective layer 300 may reduce reflectance of external light incident from the outside of the display device DD. The anti-reflective layer 300 may be formed on the sensor layer 200 through a continuous process. In one or more embodiments, the anti-reflective layer 300 may include color filters. The color filters may have a set or predetermined arrangement. For example, the color filters may be arranged in consideration of emissive colors of pixels included in the display panel 100. In in one or more embodiments, the anti-reflective layer 300 may further include a black matrix adjacent to the color filters. The anti-reflective layer 300 will be specifically described in more detail later.

In one or more embodiments of the disclosure, the sensor layer 200 may not be provided. In these embodiments, the anti-reflective layer 300 may be directly arranged on the display panel 100. In one or more embodiments of the disclosure, positions between the sensor layer 200 and the anti-reflective layer 300 may be exchanged.

In one or more embodiments of the disclosure, the display device DD may further include an optical layer arranged on the anti-reflective layer 300. For example, the optical layer may be formed on the anti-reflective layer 300 through a continuous process. The optical layer may control a direction of light incident from the display panel 100 to improve front luminance of the display device DD. For example, in one or more embodiments, the optical layer may include an organic insulation layer in which opening portions are defined to correspond to light emitting areas of the pixels included in the display panel 100, respectively, and a high refractive layer which covers the organic insulation layer and is filled in the opening portions. The high refractive layer may have a high refractive index than the organic insulation layer. For example, the display device DD may include an optical layer arranged on the anti-reflective layer 300. This optical layer may be formed through a continuous process and may be designed to control the direction of light from the display panel 100, thereby improving the front luminance of the display device DD. A “continuous process” may refer to a manufacturing method where the optical layer is formed on the anti-reflective layer 300 without interruption. The optical layer may be composed of an organic insulation layer with openings corresponding to the light-emitting areas of the pixels in the display panel 100, and a high refractive layer that covers the organic insulation layer and fills the openings. The high refractive layer has a higher refractive index than the organic insulation layer.

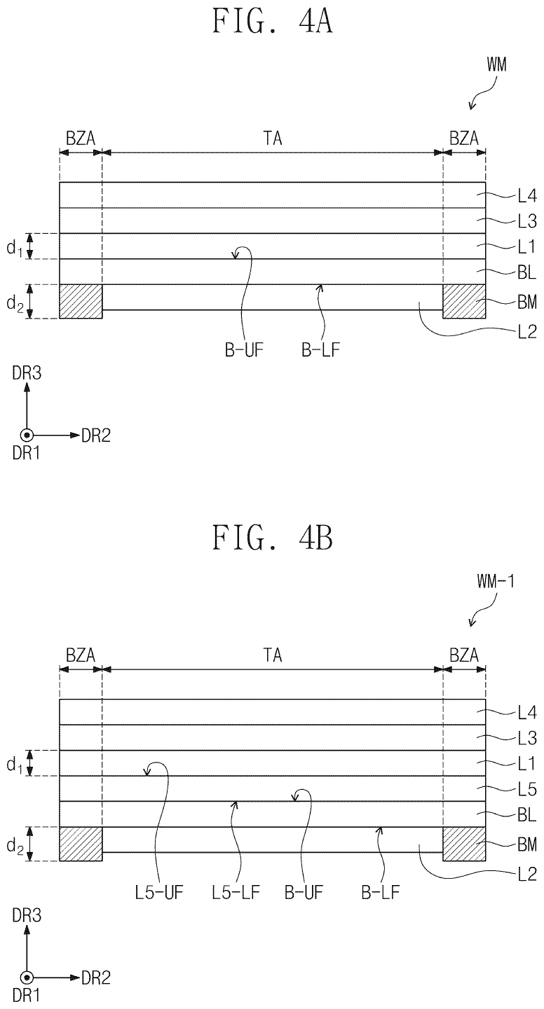

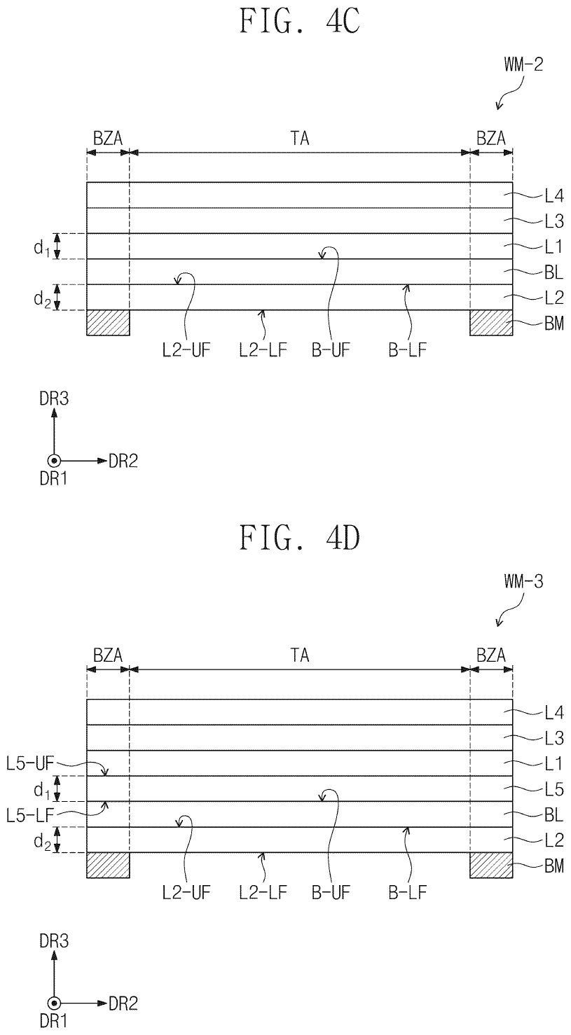

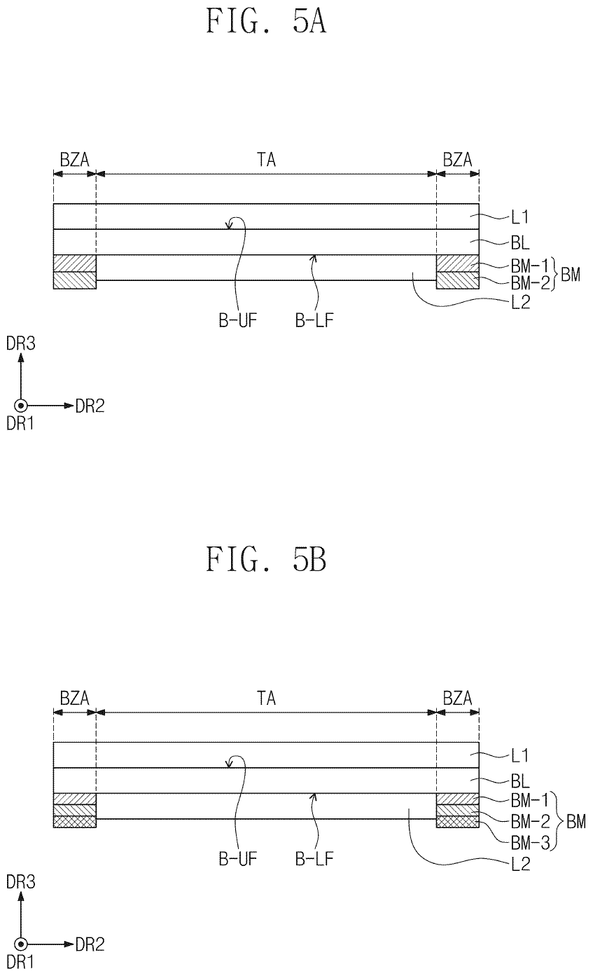

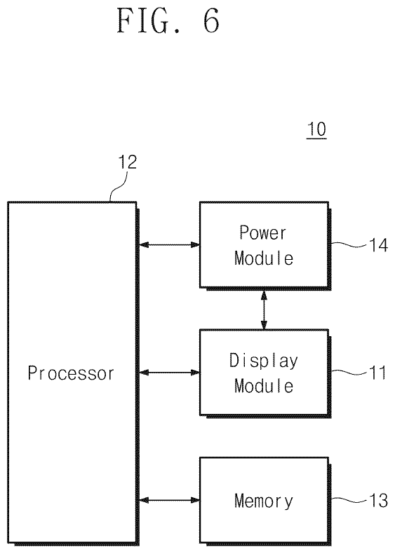

The window WM may provide a front surface of the display device DD. The window WM may include a glass film or a synthetic resin film as a base film. The window WM may further include functional layers such as an anti-reflective layer, an anti-fingerprint layer, and/or the like. The functional layers included in the window WM will be described in more detail with reference to FIG. 4A and FIG. 4B. In one or more embodiments, the window WM may further include a light blocking layer BM (see FIGS. 4A to 4D, 5A and 5B) overlapping the bezel area BZA (see FIG. 1B) described above.

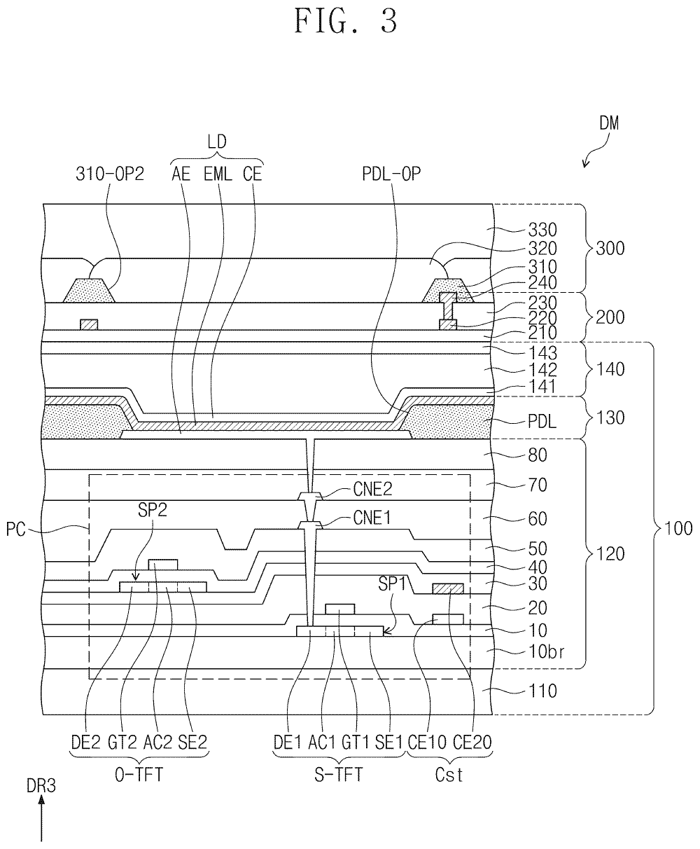

FIG. 3 is a cross-sectional view illustrating a portion of a display module according to one or more embodiments of the disclosure. FIG. 3 illustrates a partial cross-section of one light emitting element LD and a pixel circuit PC that are included in a display module DM according to one or more embodiments.

A display panel 100 included in the display module DM according to one or more embodiments may include a base substrate 110. The base substrate 110 may be a member that provides a base surface on which a circuit layer 120 is arranged.

The base substrate 110 may be a glass substrate, a metal substrate, a plastic substrate, and/or the like. However, embodiments of the present disclosure are not limited thereto, and the base substrate 110 may be an inorganic layer, an organic layer, or a composite material layer.

A buffer layer 10br may be arranged on the base substrate 110. The buffer layer 10br may prevent or reduce a phenomenon in which metal atoms or impurities are dispersed from the base substrate 110 to a first semiconductor pattern SP1 thereabove. The first semiconductor pattern SP1 may include an active region AC1 of a silicon transistor S-TFT. The buffer layer 10br may adjust a heat supply rate during a crystallization process for forming the first semiconductor pattern SP1 so that the first semiconductor pattern SP1 is uniformly (e.g., substantially uniformly) formed.

The first semiconductor pattern SP1 may be arranged on the buffer layer 10 br. The first semiconductor pattern SP1 may include a silicon semiconductor. For example, the silicon semiconductor may include an amorphous silicon, a polycrystalline silicon, and/or the like. For examples, in one or more embodiments, the first semiconductor pattern SP1 may include a low-temperature polysilicon.

As an illustration, FIG. 3 just illustrates a portion of the first semiconductor pattern SP1 arranged on the buffer layer 10br, and the first semiconductor pattern SP1 may be further arranged on another area. The first semiconductor pattern SP1 may be arranged over pixels according to a specific rule. The first semiconductor pattern SP1 may have different electrical properties according to whether the first semiconductor pattern SP1 is doped or not. The first semiconductor pattern SP1 may include a first region with high conductivity (e.g., high electric conductivity) and a second region with low conductivity (e.g., low electric conductivity). The first region may be doped with an n-type (kind) dopant or a p-type (kind) dopant. A p-type (kind) transistor may include a doped region doped with the p-type (kind) dopant, and an n-type (kind) transistor may include a doped region doped with the n-type (kind) dopant. The second region may be a non-doped region, or may be a region doped at a lower concentration than the first region.

The conductivity of the first region may be higher than the conductivity of the second region, and the first region may substantially serve as an electrode or a signal line. The second region may substantially correspond to an active area (or channel) of a transistor. For example, one portion of the first semiconductor pattern SP1 may be an active region of the transistor, another portion thereof may be a source or a drain of the transistor, and still another portion thereof may be a connection electrode or a connection signal line.

A source region SE1 (or source), the active region AC1 (or channel), and a drain region DE1 (or drain) of the silicon transistor S-TFT may be provided from the first semiconductor pattern SP1. The source region SE1 and the drain region DE1 may each extend from the active region AC1 in opposite directions on a cross-section. In one or more embodiments, a rear metal layer may be below each of the silicon transistor S-TFT and an oxide transistor O-TFT. The rear metal layer may be arranged to overlap the pixel circuit PC, and may block external light from reaching the pixel circuit PC. In one or more embodiments, the rear metal layer may be arranged between the base substrate 110 and the buffer layer 10br. In one or more embodiments, the rear metal layer may be arranged between a second insulation layer 20 and a third insulation layer 30. The rear metal layer may include a reflective metal. For example, in one or more embodiments, the rear metal layer may include silver (Ag), a silver-containing alloy, molybdenum (Mo), a molybdenum-containing alloy, aluminum (AI), an aluminum-containing alloy, an aluminum nitride (e.g., AlN), tungsten (W), a tungsten nitride (e.g., WN), copper (Cu), a p⁺ doped amorphous silicon, and/or the like. The rear metal layer may be connected to an electrode or a line, and may receive a constant voltage or a signal from the electrode or the line. According to one or more embodiments of the disclosure, the rear metal layer may be a floating electrode that is isolated from another electrode or line. In one or more embodiments of the disclosure, an inorganic barrier layer may be further arranged between the base substrate 110 and the buffer layer 10br.

A first insulation layer 10 may be arranged on the buffer layer 10br. The first insulation layer 10 may overlap, in common, a plurality of pixels and cover the first semiconductor pattern SP1. The first insulation layer 10 may be an inorganic layer and/or an organic layer, and may have a single-layer structure or a multilayer structure. In one or more embodiments, the first insulation layer 10 may include at least one of an aluminum oxide, a titanium oxide, a silicon oxide, a silicon nitride, a silicon oxynitride, a zirconium oxide, or a hafnium oxide. In one or more embodiments, the first insulation layer 10 may be a silicon oxide layer having a single-layer structure. Not only the first insulation layer 10, an insulation layer of the circuit layer 120 to be described later may also be an inorganic layer and/or an organic layer, and may have a single-layer structure or a multilayer structure. The inorganic layer may include at least one of the foregoing materials, but embodiments of the present disclosure are not limited thereto.

A gate GT1 of the silicon transistor S-TFT is arranged on the first insulation layer 10. The gate GT1 may be a portion of a metal pattern. The gate GT1 overlaps the active region AC1. The gate GT1 may function as a mask in a process of doping the first semiconductor pattern SP1. In one or more embodiments, the gate GT1 may include titanium (Ti), silver (Ag), a silver-containing alloy, molybdenum (Mo), a molybdenum-containing alloy, aluminum (Al), an aluminum-containing alloy, aluminum nitride (e.g., AlN), tungsten (W), tungsten nitride (e.g., WN), copper (Cu), indium tin oxide (e.g., ITO), indium zinc oxide (e.g., IZO), and/or the like, but embodiments of the present disclosure are not particularly limited thereto.

The second insulation layer 20 may be arranged on the first insulation layer 10 and cover the gate GT1. The third insulation layer 30 may be arranged on the second insulation layer 20. A second electrode CE20 of a storage capacitor Cst may be arranged between the second insulation layer 20 and the third insulation layer 30. In addition, a first electrode CE10 of the storage capacitor Cst may be arranged between the first insulation layer 10 and the second insulation layer 20.

A second semiconductor pattern SP2 may be arranged on the third insulation layer 30. The second semiconductor pattern SP2 may include an active region AC2 of the oxide transistor O-TFT to be described in more detail later. The second semiconductor pattern SP2 may include an oxide semiconductor. In one or more embodiments, the second semiconductor pattern SP2 may include a transparent conductive oxide (e.g., TCO) such as an indium tin oxide (e.g., ITO), an indium zinc oxide (e.g., IZO), an indium gallium zinc oxide (e.g., IGZO), a zinc oxide (e.g., ZnO), and/or an indium oxide (e.g., In₂O₃).

The oxide semiconductor may include a plurality of regions divided according to whether the transparent conductive oxide is reduced or not. A region in which the transparent conductive oxide is reduced (hereinafter referred to as a reduced region), has higher conductivity (e.g., higher electric conductivity) than a region in which the transparent conductive oxide is not reduced (hereinafter referred to as a non-reduced region). The reduced region substantially serves as a source/drain or a signal line of a transistor. The non-reduced region substantially corresponds to a semiconductor region (or active region or channel) of the transistor. For example, a partial region of the second semiconductor pattern SP2 may be the semiconductor region of the transistor, another partial region thereof may be a source region/drain region of the transistor, and still another partial region thereof may be a signal transfer region.

A source region SE2 (or source), the active region AC2 (or channel), and a drain region DE2 (or drain) of the oxide transistor O-TFT may be provided from the second semiconductor pattern SP2. The source region SE2 and the drain region DE2 may each extend from the active region AC2 in opposite directions on a cross-section.

A fourth insulation layer 40 may be arranged on the third insulation layer 30. The fourth insulation layer 40 may overlap, in common, the plurality of pixels and cover the second semiconductor pattern SP2. In one or more embodiments, the fourth insulation layer 40 may be provided in the form of an insulation pattern that overlaps a gate GT2 of the oxide transistor O-TFT, and exposes each of the source region SE2 and the drain region DE2 of the oxide transistor O-TFT.

The gate GT2 of the oxide transistor O-TFT is arranged on the fourth insulation layer 40. The gate GT2 of the oxide transistor O-TFT may be a portion of a metal pattern. The gate GT2 of the oxide transistor O-TFT overlaps the active region AC2.

A fifth insulation layer 50 may be arranged on the fourth insulation layer 40 and cover the gate GT2. A first connection electrode CNE1 may be arranged on the fifth insulation layer 50. In one or more embodiments, the first connection electrode CNE1 may be connected to the drain region DE1 of the silicon transistor S-TFT through a contact hole passing through the first to fifth insulation layers 10, 20, 30, 40 and 50.

A sixth insulation layer 60 may be arranged on the fifth insulation layer 50. A second connection electrode CNE2 may be arranged on the sixth insulation layer 60. The second connection electrode CNE2 may be connected to the first connection electrode CNE1 through a contact hole passing through the sixth insulation layer 60. A seventh insulation layer 70 may be arranged on the sixth insulation layer 60, and may cover the second connection electrode CNE2. An eighth insulation layer 80 may be arranged on the seventh insulation layer 70.

Each of the sixth insulation layer 60, the seventh insulation layer 70, and the eighth insulation layer 80 may be an organic layer. For example, each of the sixth insulation layer 60, the seventh insulation layer 70, and the eighth insulation layer 80 may independently include a general purpose polymer such as a benzocyclobutene (BCB) based polymer, polyimide, hexamethyldisiloxane (HMDSO), polymethyl methacrylate (PMMA), polystyrene (PS), a polymer derivative having a phenol-based group, an acryl-based polymer, an imide-based polymer, an acryl ether-based polymer, an amide-based polymer, a fluorine-based polymer, a p-xylene-based polymer, a vinyl alcohol-based polymer, a blend thereof, and/or the like. For example, the sixth, seventh, and eighth insulation layers (60, 70, and 80) may each be an organic layer. These layers may independently include various general-purpose polymers such as benzocyclobutene (BCB) based polymer, polyimide, hexamethyldisiloxane (HMDSO), polymethyl methacrylate (PMMA), polystyrene (PS), and/or other polymer derivatives and/or blends.

The light emitting element LD may include a first electrode AE (or pixel electrode), a light emitting layer EML, and a second electrode CE (or common electrode). Each of the light emitting layer EML and the second electrode CE may be provided, in common, in the plurality of pixels.

The first electrode AE of the light emitting element LD may be arranged on the eighth insulation layer 80. The first electrode AE of the light emitting element LD may be a (semi-) transmissive electrode or a reflective electrode. According to one or more embodiments of the disclosure, the first electrode AE of the light emitting element LD may include a reflective layer made of silver (Ag), magnesium (Mg), aluminum (AI), platinum (Pt), palladium (Pd), gold (Au), nickel (Ni), neodymium (Nd), iridium (Ir), chromium (Cr), a compound thereof, and/or the like, and a transparent or semi-transparent electrode layer provided on the reflective layer. The transparent or semi-transparent electrode layer may include at least one selected from the group consisting of an indium tin oxide (e.g., ITO), an indium zinc oxide (e.g., IZO), an indium gallium zinc oxide (e.g., IGZO), a zinc oxide (e.g., ZnO), an indium oxide (e.g., In₂O₃), and an aluminum-doped zinc oxide (e.g., AZO). For example, in one or more embodiments, the first electrode AE of the light emitting element LD may include a stack structure of ITO/Ag/ITO.

A pixel defining film PDL may be arranged on the eighth insulation layer 80. The pixel defining film PDL may include the same material and be formed through the same process. The pixel defining film PDL may have a light absorbing property, and for example, in one or more embodiments, the pixel defining film PDL may have a black color. The pixel defining film PDL may include a black component (e.g., black coloring agent). The black component may include a black dye and/or a black pigment. The black component may include a carbon black, a metal such as chrome, or an oxide thereof. The pixel defining film PDL may correspond to a light blocking pattern having a light blocking property.

The pixel defining film PDL may cover a portion of the first electrode AE of the light emitting element LD. For example, an opening PDL-OP that exposes a portion of the first electrode AE of the light emitting element LD may be defined in the pixel defining film PDL. The pixel defining film PDL may increase a distance between the second electrode CE and an edge of the first electrode AE of the light emitting element LD. Thus, the pixel defining film PDL may serve to prevent or reduce an arc and/or the like from occurring at the edge of the first electrode AE.

In one or more embodiments, a hole control layer may be arranged between the first electrode AE and the light emitting layer EML. The hole control layer may include a hole transport layer, and may further include a hole injection layer. An electron control layer may be arranged between the light emitting layer EML and the second electrode CE. The electron control layer may include an electron transport layer, and may further include an electron injection layer. The hole control layer and the electron control layer may each be formed, in common, in the plurality of pixels by using an open mask.

An encapsulation layer 140 may be arranged on the light emitting element layer 130. The encapsulation layer 140 may include an inorganic layer 141, an organic layer 142, and an inorganic layer 143 which are stacked in sequence, but layers constituting the encapsulation layer 140 are not limited thereto.

The inorganic layers 141 and 143 may protect the light emitting element layer 130 from moisture and oxygen, and the organic layer 142 may protect the light emitting element layer 130 from foreign matter such as dust particles. In one or more embodiments, the inorganic layers 141 and 143 may each include a silicon nitride layer, a silicon oxynitride layer, a silicon oxide layer, a titanium oxide layer, an aluminum oxide layer, and/or the like. The organic layer 142 may include an acrylic organic layer. Embodiments of the present disclosure are not limited thereto.

A sensor layer 200 may be arranged on the display panel 100. The sensor layer 200 may be referred to as a sensor, an input sensing layer, or an input sensing panel. The sensor layer 200 may include a base layer 210, a first conductive layer 220, a sensing insulation layer 230, and a second conductive layer 240.

The base layer 210 may be directly arranged on the display panel 100. In one or more embodiments, the base layer 210 may be an inorganic layer including at least one of a silicon nitride, a silicon oxynitride, or a silicon oxide. In one or more embodiments, the base layer 210 may be an organic layer including an epoxy-based resin, an acrylic-based resin, or an imide-based resin. The base layer 210 may have a single-layer structure, or may have a multilayer structure in which layers are stacked in the third direction DR3.

Each of the first conductive layer 220 and the second conductive layer 240 may have a single-layer structure, or may have a multilayer structure in which layers are stacked in the third direction DR3. The first conductive layer 220 and the second conductive layer 240 may include conductive lines that define a mesh-shaped sensing electrode. The conductive lines may not overlap the opening PDL-OP but overlap the pixel defining film PDL.

In one or more embodiments, the conductive layer (i.e., the first conductive layer 220 and/or the second conductive layer 240) having a single-layer structure may include a metal layer or a transparent conductive layer. For example, the conductive layer (either the first conductive layer 220 or the second conductive layer 240) may have a single-layer structure that includes either a metal layer or a transparent conductive layer. The metal layer may include (e.g., may be composed of) molybdenum, silver, titanium, copper, aluminum, or an alloy thereof. The transparent conductive layer may include (e.g., may be) a transparent conductive oxide such as an indium tin oxide (ITO), an indium zinc oxide (IZO), a zinc oxide (e.g., ZnO), and/or an indium zinc tin oxide (IZTO). In addition, the transparent conductive layer may include (e.g., may be) a conductive polymer such as poly(3,4-ethylenedioxythiophene) (PEDOT), a metal nanowire, graphene, and/or the like. For example, the transparent conductive layer may include or composed of materials such as indium tin oxide (ITO), indium zinc oxide (IZO), zinc oxide (e.g., ZnO), indium zinc tin oxide (IZTO), conductive polymers like poly (3,4-ethylenedioxythiophene) (PEDOT), metal nanowires, graphene, and/or similar materials.

In one or more embodiments, the conductive layer having a multilayer structure may include metal layers. The metal layers may have a three-layer structure of, for example, titanium/aluminum/titanium. In one or more embodiments, the conductive layer having a multilayer structure may include at least one metal layer and at least one transparent conductive layer.

The sensing insulation layer 230 may be arranged between the first conductive layer 220 and the second conductive layer 240. In one or more embodiments, the sensing insulation layer 230 may include an inorganic film. The inorganic film may include at least one of an aluminum oxide, a titanium oxide, a silicon oxide, a silicon nitride, a silicon oxynitride, a zirconium oxide, or a hafnium oxide.

In one or more embodiments, the sensing insulation layer 230 may include an organic film. The organic film may include at least one of an acryl-based resin, a methacryl-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

An anti-reflective layer 300 may be arranged on the sensor layer 200. The anti-reflective layer 300 may include a division layer 310, a plurality of color filters 320, and a planarization layer 330.

The anti-reflective layer 300 may reduce external light reflectance. The anti-reflective layer 300 may include the plurality of color filters 320, and the plurality of color filters 320 may have a set or predetermined arrangement. In the plurality of color filters 320, the arrangement may be determined in consideration of emissive colors of pixels included in the display panel 100. In the display module DM according to one or more embodiments, the anti-reflective layer 300 may not include (e.g., may exclude) a retarder and a polarizer, and may reduce reflectance of the display module DM through the plurality of color filters 320. In the display module DM according to one or more embodiments, the anti-reflective layer 300 may not include (e.g., may exclude) a polarizing film or a polarizing layer. For example, the anti-reflective layer 300 may be designed to reduce external light reflectance and includes a plurality of color filters 320 arranged based on the emissive colors of the pixels in the display panel 100. In some embodiments, the anti-reflective layer 300 does not include any retarder, polarizer, polarizing film, or polarizing layer, and instead reduces reflectance through the color filters 320.

A material constituting the division layer 310 is not particularly limited as long as being a material that absorbs light. The division layer 310 may be a layer having a black color, and in one or more embodiments, the division layer 310 may include a black component (black coloring agent). The black component may include a black dye and/or a black pigment. In one or more embodiments, the black component may include a carbon black, a metal such as chrome, or an oxide thereof.

The division layer 310 may cover the second conductive layer 240 of the sensor layer 200. The division layer 310 may prevent or reduce external light from being reflected by the second conductive layer 240. The division layer 310 may overlap a portion of the pixel defining film PDL.

A division opening 310-OP2 may be defined in the division layer 310. The division opening 310-OP2 may overlap the first electrode AE of the light emitting element LD. One of the plurality of color filters 320 may overlap the first electrode AE of one light emitting element LD. One of the plurality of color filters 320 may cover the division opening 310-OP2. Each of the plurality of color filters 320 may be in contact with the division layer 310.

The planarization layer 330 may cover the division layer 310 and the color filters 320. The planarization layer 330 may include an organic material, and a flat surface may be provided on a top surface of the planarization layer 330. In one or more embodiments of the disclosure, the planarization layer 330 may not be provided.

FIGS. 4A and 4B are each a cross-sectional view of a window according to one or more embodiments of the disclosure. The windows illustrated in FIGS. 4A and 4B may each be the window WM according to one or more embodiments illustrated in FIGS. 1B, 2, and/or the like. The window WM or WM-1 according to one or more embodiments illustrated in each of FIGS. 4A and 4B may be used as a cover window of the display device DD according to one or more embodiments described with reference to FIGS. 1A, 1B, and 2.

Referring to FIG. 4A, the window WM according to one or more embodiments of the disclosure includes a base layer BL, a first layer L1, a second layer L2, a third layer L3, and a fourth layer L4. In the window WM according to one or more embodiments, the second layer L2, the base layer BL, the first layer L1, the third layer L3, and the fourth layer L4 may be stacked in sequence (e.g., in the stated order). The first layer L1, the third layer L3, and the fourth layer L4 may be layers arranged above the base layer BL on the basis of the third direction DR3, and the second layer L2 may be a layer arranged below the base layer BL on the basis of the third direction DR3.

The base layer BL may include a transparent material. In one or more embodiments, the base layer BL may be glass, strengthened glass, or a polymer film. In one or more embodiments, the base layer BL may be a chemically strengthened glass substrate. In embodiments in which the base layer BL is a chemically strengthened glass substrate, the base layer BL may have a small thickness and also have increased mechanical strength. Accordingly, the base layer BL may be used for a window of a foldable display device. In embodiments in which the base layer BL includes a polymer film, the base layer BL may include a polyimide (PI) film and/or a polyethylene terephthalate (PET) film. The base layer BL of the window WM may have a multilayer structure or a single-layer structure. For example, in one or more embodiments, the base layer BL may have a structure, in which a plurality of polymer films are coupled to each other through an adhesive member, or may have a structure in which a glass substrate and a polymer film are coupled to each other through an adhesive. In one or more embodiments, the base layer BL may be made of a flexible material.

The base layer BL may have a thickness of, for example, about 23 micrometers (μm) to about 188 μm. In one or more embodiments, the thickness of the base layer BL may be about 50 μm to about 100 μm. As an example, FIGS. 4A to 4D illustrate the base layer BL having a rectangular shape. However, embodiments of the present disclosure are not limited thereto, and the base layer BL according to one or more embodiments may have a shape in which an edge portion of a top surface of the base layer BL is rounded with a curved surface. For example, in one or more embodiments, the base layer BL may have a shape in which an edge portion of the top surface, which overlaps the bezel area BZA (see FIG. 1B), is rounded with a curved surface.

Each of the first layer L1 and the second layer L2 is a layer having a lower refractive index than the base layer BL, and may be a layer for reducing surface reflectance of the window WM.

The first layer L1 may be arranged on the base layer BL. In one or more embodiments, the first layer L1 may be a layer directly arranged on the base layer BL. In one or more embodiments, the first layer L1 may be in contact with a top surface B-UF of the base layer BL. A bottom surface B-LF of the base layer BL may be a surface adjacent to the display module DM (see FIG. 2) described above, and the top surface B-UF of the base layer BL may be a surface which opposes the bottom surface B-LF of the base layer BL in the third direction DR3 and is spaced and/or apart (e.g., spaced apart or separated) from the display module DM (see FIG. 2) described above.

The second layer L2 may be arranged below the base layer BL. The second layer L2 may be a layer directly arranged below the base layer BL. The second layer L2 may be in contact with the bottom surface B-LF of the base layer BL. In one or more embodiments, the base layer BL may be spaced and/or apart (e.g., spaced apart or separated) from the display module DM (see FIG. 2) with the second layer L2 therebetween.

Each of the first layer L1 and the second layer L2 may include a material having a low refractive index and excellent or suitable adhesion to the base layer BL. The first layer L1 may include a first material, and the second layer L2 may include a second material. Each of the first material and the second material may include a material having a lower refractive index than a material included in the base layer BL.

Each of the first material included in the first layer L1 and the second material included in the second layer L2 may include a magnesium oxide (e.g., MgO), a magnesium fluoride (e.g., MgF₂), and a yttrium oxyfluoride (e.g., YOF). In one or more embodiments, each of the first layer L1 and the second layer L2 may include a solid solution in which magnesium oxide, magnesium fluoride, and yttrium oxyfluoride are mixed.

In one or more embodiments, at least one of the first layer L1 or the second layer L2 may further include SiₓO_{y}Mg_{z}AlᵤNᵥ. In SiₓO_{y}Mg_{z}AlᵤNᵥ, x, y, z, u, and v may each independently be a value of 0 to 1, and a sum total of x, y, z, u, and v (i.e., x+y+z+u+v) may be 1 or less. Here, at least two selected from among x, y, z, u, and v may each be more than 0 and 1 or less, provided that a case where x and y may each independently be more than 0 and 1 or less and remaining z, u, and v are each 0 is excluded. In one or more embodiments, in SiₓO_{y}Mg_{z}AlᵤNᵥ, u and v may each be 0, x, y, and z may each independently be more than 0 and 1 or less.

The first layer L1 may have a thickness d₁ of about 100 nm or less. For

example, in one or more embodiments, the thickness d₁ of the first layer L1 may be about 65 nm to about 85 nm. The second layer L2 may have a thickness d₂ of about 100 nm or less. For example, in one or more embodiments, the thickness d₂ of the second layer L2 may be about 65 nm to about 85 nm. In a case in which each of the thickness d₁ of the first layer L1 and the thickness d₂ of the second layer L2 is less than about 65 nm, the surface reflectance of the window WM may not be sufficiently reduced. In a case in which each of the thickness d1 of the first layer L1 and the thickness d2 of the second layer L2 is more than about 85 nm, mechanical strength of the window WM may be reduced to decrease durability, and a total thickness of the window WM may be increased to excessively increase an overall thickness of the display device.

A refractive index of the first layer L1 at the wavelength of about 550 nm may be about 1.3 to about 1.5. A refractive index of the second layer L2 at the wavelength of about 550 nm may be about 1.3 to about 1.5. In the window WM according to one or more embodiments, the refractive index of each of the first layer L1 and the second layer L2 at the wavelength of about 550 nm may be about 1.38 to about 1.42. As the refractive index of each of the first layer L1 and the second layer L2 at the wavelength of about 550 nm satisfies the foregoing range, the surface reflectance of the window WM may be reduced.

The first layer L1 and the second layer L2 may each be formed through an ion-assisted deposition process. The first layer L1 may be made of magnesium oxide, magnesium fluoride, and yttrium oxyfluoride as described above. In a process of forming each of the first layer L1 and the second layer L2, each of magnesium oxide, magnesium fluoride, and yttrium oxyfluoride may be deposited in the form of particles onto the top surface B-UF and the bottom surface B-LF of the base layer BL, and also during the depositing process, ionized argon (Ar) or oxygen (O₂) gas may be provided together, thereby improving the adhesion of the deposited film to the surface(s) of the base layer BL.

Each of the first layer L1 and the second layer L2 may have a single-layer structure made of a single material. As described above, each of the first layer L1 and the second layer L2 may be a single layer made of the solid solution in which magnesium oxide, magnesium fluoride, and yttrium oxyfluoride are mixed. For example, each of the first layer L1 and the second layer L2 may not include (e.g., may exclude) a plurality of layers.

The third layer L3 may be arranged on the first layer L1. The third layer L3 may be a layer for improving an adhesion between the first layer L1 and the fourth layer L4. The third layer L3 may be an adhesion promoter having excellent or suitable adhesion to each of the first layer L1 and the fourth layer L4 to improve the adhesion between the first layer L1 and the fourth layer L4. The third layer L3 may be directly arranged on the first layer L1. The third layer L3 may be in contact with a top surface of the first layer L1.

The third layer L3 may have a low refractive characteristic, and may also have excellent or suitable mechanical strength and include a material for improving the adhesion. The third layer L3 may include a third material, and the third layer L3 may include a material having a lower refractive index than a material included in the base layer BL. In one or more embodiments, the third material included in the third layer L3 may include silicon oxide (e.g., SiO₂) and aluminum oxide (e.g., Al₂O₃). In one or more embodiments, the third layer L3 may include Si₉Al₂O₁₀. In one or more embodiments, the third layer L3 may include at least one of, for example, silica, fused silica, fluorine-doped fused silica, magnesium fluoride (e.g., MgF₂), calcium fluoride (e.g., CaF₂), aluminum fluoride (e.g., AlF₃), yttrium fluoride (e.g., YF₃), ytterbium fluoride (e.g., YbF₃), or magnesium oxide (e.g., MgO).

In one or more embodiments, the third layer L3 may include silicon oxide (e.g., SiO₂) and aluminum oxide (e.g., Al₂O₃). The third layer L3 may include, for example, a solid solution in which aluminum oxide and silicon oxide are mixed. As the third layer L3 includes the solid solution including aluminum oxide and silicon oxide, the adhesion to the first layer L1 including the magnesium oxide like the third layer L3 may be improved. The third layer L3 may be formed through substantially the same ion-assisted deposition process as the first layer L1.

In one or more embodiments, the third layer L3 may further include SiₓO_{y}Mg_{z}AlᵤNᵥ. In SiₓO_{y}Mg_{z}AlᵤNᵥ, x, y, z, u, and v may each independently be a value of 0 to 1, and a sum total of x, y, z, u, and v (i.e., x+y+z+u+v) may be 1 or less. Here, at least two selected from among x, y, z, u, and v may each be more than 0 and or less, provided that a case where x and y may each independently be more than 0 and 1 or less and remaining z, u, and v are each 0 is excluded. In one or more embodiments, in SiₓO_{y}Mg_{z}AlᵤNᵥ, u and v may be each 0, and x, y, and z may each independently be more than 0 and 1 or less.

The third layer L3 may have a thickness of, for example, about 5 nm to about 30 nm. In a case in which the thickness of the third layer L3 is less than about 5 nm, an effect of improving the adhesion between the first layer L1 and the fourth layer L4 may not be achieved, and the mechanical strength of the window WM may be reduced. In a case in which the thickness of the third layer L3 is more than about 30 nm, the reflectance of the window WM may be increased, and the total thickness of the window WM may be increased to excessively increase an overall thickness of the display device.

A refractive index of the third layer L3 at the wavelength of about 550 nm may be about 1.3 to about 1.6. In the window WM according to one or more embodiments, the refractive index of the third layer L3 at the wavelength of about 550 nm may be about 1.46 to about 1.50. As the refractive index of the third layer L3 at the wavelength of about 550 nm satisfies the foregoing range, the surface reflectance of the window WM may be reduced.

The third layer L3 may have a single-layer structure made of a single material. As described above, the third layer L3 may be a single layer formed of the solid solution in which magnesium oxide and silicon oxide (e.g., silica) are mixed. For example, the third layer L3 may not include (e.g., may exclude) a plurality of layers.

The fourth layer L4 may be arranged on the third layer L3. The fourth layer L4 may be a layer capable of improving slip resistance, scratch resistance, and/or the like, of the surface of the window WM. In one or more embodiments, the fourth layer L4 may be an anti-fingerprint layer that has excellent or suitable fingerprint resistance and suppresses surface wear. The fourth layer L4 may be directly arranged on the third layer L3. The fourth layer L4 may be arranged on an uppermost layer of the window WM, and a top surface of the fourth layer L4 may define the uppermost layer of the window WM.

The fourth layer L4 may include a material which is excellent or suitable in scratch resistance and slip resistance and has a low refractive characteristic. In one or more embodiments, the fourth layer L4 may include a fluorine-containing polymer. In one or more embodiments, the fourth layer L4 may include, for example, a perfluoropolyether (PFPE) compound. In one or more embodiments, the fourth layer L4 may include perfluoropolyether silane, perfluoroalkylether alkoxysilane, perfluoroalkylether copolymer, and/or the like. As the fourth layer L4 includes the perfluoropolyether compound, the fingerprint resistance and the scratch resistance of the fourth layer L4 may be improved.

The fourth layer L4 may have a thickness of, for example, about 5 nm to about 40 nm. In a case in which the thickness of the fourth layer L4 is less than about 5 nm, the fingerprint resistance and the scratch resistance of the window WM may be reduced. In a case in which the thickness of the fourth layer L4 is more than about 40 nm, the reflectance of the window WM may be increased, and the total thickness of the window WM may be increased to excessively increase the overall thickness of the display device.

A refractive index of the fourth layer L4 at the wavelength of about 550 nm may be about 1.3 to about 1.5. In the window WM according to one or more embodiments, the refractive index of the fourth layer L4 at the wavelength of about 550 nm may be about 1.30 to about 1.35. As the refractive index of the fourth layer L4 at the wavelength of about 550 nm satisfies the foregoing range, the surface reflectance of the window WM may be reduced.

In the window WM according to one or more embodiments, the reflectance of the surface of the window WM at the wavelength of about 550 nm may be about 5.0% or less. In the window WM according to one or more embodiments, the fourth layer L4 may be arranged as the uppermost layer, and a reflectance of a top surface of the third layer L3 at the wavelength of about 550 nm may be about 5.0% or less. A reflectance of a top surface of the fourth layer L4 at the wavelength of about 550 nm may be about 3.0% to about 4.2%. The “reflectance” of the window WM used herein is defined as a ratio of light reflected to the outside to light incident inward from the outside of the window WM. The light reflected to the outside may include both (e.g., simultaneously) of regular reflection light, which is reflected at the same angle after being incident, and diffuse reflection light which is reflected in one or more directions. For example, the reflectance used herein is defined as a specular component included (SCI)-reflectance.

The window WM according to one or more embodiments may further include a light blocking layer BM arranged below the base layer BL. The light blocking layer BM may be a layer for preventing or reducing light leakage of the display panel. The light blocking layer BM may be provided on the bottom surface B-LF of the base layer BL of the window WM and be in contact with a top surface of the display module DM (FIG. 2) arranged below the window WM.

The light blocking layer BM may overlap a bezel area BZA of the window WM. The light blocking layer BM may cover the bezel area BZA. The light blocking layer BM may substantially define the bezel area BZA of the window WM. The light blocking layer BM may have a shape extending along the bezel area BZA of the window WM. In one or more embodiments, the light blocking layer BM may be an ink print layer. In one or more embodiments, the light blocking layer BM may be a layer provided by including a pigment and/or a dye.

The light blocking layer BM may be arranged on the bottom surface B-LF of the base layer BL. The light blocking layer BM may be provided on the bottom surface B-LF of the base layer BL, which is adjacent to the display module DM (FIG. 2). In the window WM according to one or more embodiments illustrated in FIG. 4A, each of the second layer L2 and the light blocking layer BM may be arranged on the bottom surface B-LF of the base layer BI. The second layer L2 may overlap the transmission area TA but not overlap the bezel area BZA. The second layer L2 may not overlap the light blocking layer BM on a plane (e.g., in a plan view). The light blocking layer BM will be described in more detail with reference to FIGS. 5A and 5B.

Referring to FIG. 4B, the window WM-1 according to one or more embodiments may further include a fifth layer L5 arranged between the base layer BL and the first layer L1. For example, the window WM-1 according to one or more embodiments illustrated in FIG. 4B may include a second layer L2, the base layer BL, the fifth layer L5, the first layer L1, a third layer L3, and a fourth layer L4 which are stacked in sequence. The first layer L1 may be arranged apart from the base layer BL with the fifth layer L5 therebetween. For example, the first layer L1 may be arranged on a top surface L5-UF of the fifth layer L5, and a bottom surface L5-LF of the fifth layer is in contact with the top surface B-UF of the base layer BL. The fifth layer L5 used herein may be referred to as a hard coating layer.

In the window WM-1 according to one or more embodiments, the fifth layer L5 may function to protect the base layer BL or display module DM (see FIG. 2). The fifth layer L5 may be directly arranged on a top surface (e.g., top surface B-UF) of the base layer BL. However, an arranged position of the fifth layer L5 is not limited to one or more embodiments illustrated in FIG. 4B, and in the window WM-1 according to one or more embodiments, the fifth layer L5 may be arranged between the base layer BL and the second layer L2. In one or more embodiments, the window WM-1 may further include a sixth layer arranged between the base layer BL and the second layer L2, in addition to the fifth layer L5 arranged between the base layer BL and the first layer L1.

The fifth layer L5 may be formed of a hard coating layer resin including at least one of an organic-based composition, an inorganic-based composition, or an organic/inorganic composite composition. For example, a hard coating agent constituting the hard coating layer may be a composition for hard coating including at least one of an acrylate-based compound, a siloxane compound, or a silsesquioxane compound. In one or more embodiments, the hard coating agent may further include an inorganic particle. The fifth layer L5 may be an organic layer, an inorganic layer, or an organic/inorganic composite material layer.

The inorganic particle in the hard coating agent may be used for improvement in hardness of the fifth layer L5. The inorganic particle may include at least one oxide or nitride of elements such as silicon, titanium, aluminum, zirconium, or zinc. For example, the inorganic particle may include at least one of SiO₂, TiO₂, Al₂O₃, ZrO₂, ZnO, AlN, or Si₃N₄. In one or more embodiments, the inorganic particle may be surface-treated with an organic material, such as silane, in order to increase dispersion in the composition for hard coating.

In one or more embodiments, the window WM-1 according to one or more embodiments may further include an adhesive layer arranged between the fifth layer L5 and the base layer BL. The adhesive layer may couple the fifth layer L5 and the base layer BL to each other. The adhesive layer may include a silicon-based resin, an acryl-based resin, or a urethane-based resin.

FIGS. 4C and 4D are each a cross-sectional view illustrating a window according to one or more embodiments of the disclosure. FIGS. 4C and 4D respectively illustrate windows WM-2 and WM-3 according to one or more embodiments each of which is different from the windows WM and WM-1 illustrated in FIGS. 4A and 4B. The window WM-2 or WM-3 according to one or more embodiments illustrated in FIGS. 4C and 4D, respectively, may be used as a cover window of the display device DD according to one or more embodiments described with reference to FIGS. 1A, 1B, and 2. Hereinafter, the windows WM-2 and WM-3 according to one or more embodiments of the disclosure will be each described by avoiding the content in common with the content described with reference to FIGS. 4A and 4B for conciseness, and in more details in terms of differences. In other words, the descriptions of FIG. 4C and FIG. 4D may also refer to the descriptions of FIG. 4A and FIG. 4B for the like components.

The window WM-2 illustrated in FIG. 4C is different from the window WM illustrated in FIG. 4A in terms of arranged positions of a second layer L2 and a light blocking layer BM. Also, the window WM-3 illustrated in FIG. 4D is different from the window WM-1 illustrated in FIG. 4B in terms of arranged positions of a second layer L2 and a light blocking layer BM.

Referring to FIGS. 4C and 4D, in each of the windows WM-2 and WM-3 according to one or more embodiments, the second layer L2 may be arranged below the base layer BL, and the light blocking layer BM may be arranged below the second layer L2. The second layer L2 may be arranged on a bottom surface B-LF of the base layer BL, and the light blocking layer BM may be arranged on a bottom surface L2-LF of the second layer L2. The bottom surface L2-LF of the second layer L2 may be a surface adjacent to the display module DM (see FIG. 2) described above, and a top surface L2-UF of the second layer L2 may be a surface which opposes the bottom surface L2-LF of the second layer L2 in the third direction DR3 and is spaced and/or apart (e.g., spaced apart or separated) from the display module DM (see FIG. 2) described above. The second layer L2 may be arranged on the bottom surface B-LF of the base layer BL, which overlaps a transmission area TA and a bezel area BZA. The second layer L2 may overlap the transmission area TA and the bezel area BZA on a plane. The light blocking layer BM may be arranged on the bottom surface L2-LF of the second layer L2, which overlaps the bezel area BZA. The light blocking layer BM may overlap the bezel area BZA on a plane (e.g., in a plan view).

FIGS. 5A and 5B are each a cross-sectional view illustrating some components of a window according to one or more embodiments of the disclosure. In FIGS. 5A and 5B, the third layer L3, the fourth layer L4, and the fifth layer L5 of each of the windows WM, WM-1, WM-2 and WM-3 illustrated in FIGS. 4A to 4D are not illustrated for concise description.

Referring to FIG. 5A, a light blocking layer BM may include a first light blocking layer BM-1 arranged below a base layer BL, and a second light blocking layer

BM-2 arranged below the first light blocking layer BM-1. In one or more embodiments, the first light blocking layer BM-1 may be arranged on a bottom surface B-LF of the base layer BL, and the second light blocking layer BM-2 may be arranged on a bottom surface of the first light blocking layer BM-1. In one or more embodiments, respective widths of the first light blocking layer BM-1 and the second light blocking layer BM-2 may be the same, but embodiments of the present disclosure are not limited thereto. Here, the width may indicate a dimension (e.g., a length) in the second direction DR2.

The light blocking layer BM may have a thickness of about 5 μm to about 20 μm. The thickness used herein may indicated an average length in the third direction DR3. In a case in which the thickness of the light blocking layer BM is less than about 5 μm, the light leakage of the display panel DP may be difficult to prevent or reduce. In a case in which the thickness of the light blocking layer BM is more than about 20 μm, the total thickness of the window WM may be increased.

The light blocking layer BM may have a multilayer structure. As illustrated in FIG. 5A, the light blocking layer BM according to one or more embodiments may have a structure in which two layers are stacked. The light blocking layer BM may include the first light blocking layer BM-1 arranged below the base layer BL, and the second light blocking layer BM-2 arranged below the first light blocking layer BM-1. The first light blocking layer BM-1 may be provided on the bottom surface B-LF of the base layer BL. The second light blocking layer BM-2 may be provided on the bottom surface of the first light blocking layer BM-1. The second light blocking layer BM-2 may be arranged apart from the base layer BL with the first light blocking layer BM-1 therebetween.

In one or more embodiments, the thickness of the light blocking layer BM including the first light blocking layer BM-1 and the second light blocking layer BM-2 may be, for example, about 12 μm to about 15 μm. In one or more embodiments, a thickness of the first light blocking layer BM-1 may be about 3 μm to about 8 μm, and a thickness of the second light blocking layer BM-2 may be about 5 μm to about 10 μm. In embodiments in which the first light blocking layer BM-1 and the second light blocking layer BM-2 have the foregoing thickness ranges, an excellent or suitable effect of preventing or reducing light leakage may be provided without chrominance variation. Although FIG. 5A illustrates the first light blocking layer BM-1 and the second light blocking layer BM-2 having the same thickness, embodiments of the present disclosure are not limited thereto.

Each of the first light blocking layer BM-1 and the second light blocking layer BM-2 may include at least one of an acrylic urethane-based compound, an epoxy-based compound, a polyester-based compound, or an epoxy ester-based compound. In one or more embodiments, the first light blocking layer BM-1 and the second light blocking layer BM-2 may include different materials. For example, in one or more embodiments, the first light blocking layer BM-1 may include an acrylic urethane-based compound and/or a polyester-based compound, and the second light blocking layer BM-2 may include an epoxy-based compound and/or an epoxy ester-based compound. However, embodiments of the present disclosure are not limited thereto, and the first light blocking layer BM-1 and the second light blocking layer BM-2 may include the same material. As the first light blocking layer BM-1 and the second light blocking layer BM-2 include one or more of the foregoing materials, high heat resistance may be exhibited even in a deposition process at about 150° C., and thus a crack may not be initiated and excellent or suitable chrominance (AE) may be exhibited.

Referring to FIG. 5B, a light blocking layer BM according to one or more embodiments may have a structure in which three layers are stacked. The light blocking layer BM may include a first light blocking layer BM-1 arranged below a base layer BL, a second light blocking layer BM-2 arranged below the first light blocking layer BM-1, and a third light blocking layer BM-3 arranged below the second light blocking layer BM-2. For example, the first light blocking layer BM-1, the second light blocking layer BM-2, and the third light blocking layer BM-3 may be stacked in sequence below the base layer BL. The first light blocking layer BM-1 may be provided on a bottom surface B-LF of the base layer BL. The second light blocking layer BM-2 may be provided on a bottom surface of the first light blocking layer BM-1, and the third light blocking layer BM-3 may be provided on a bottom surface of the second light blocking layer BM-2.

A thickness of the light blocking layer BM including the first light blocking layer BM-1, the second light blocking layer BM-2, and the third light blocking layer BM-3 may be, for example, about 12 μm to about 15 μm. In one or more embodiments, a thickness of the first light blocking layer BM-1 may be about 2 μm to about 5 um, a thickness of the second light blocking layer BM-2 may be about 3 μm to about 5 μm, and a thickness of the third light blocking layer BM-3 may be about 3 μm to about 5 μm. In embodiments in which the first to third light blocking layers BM-1, BM-2 and BM-3 have the foregoing thickness ranges, the excellent or suitable effect of preventing or reducing light leakage may be provided without chrominance variation. Although FIG. 5B illustrates the first to third light blocking layers BM-1, BM-2 and BM-3 having substantially the same thickness, embodiments of the present disclosure are not limited thereto. For example, in one or more embodiments, the first to third light blocking layers BM-1, BM-2 and BM-3 may have different thicknesses, or at least one selected from among the first to third light blocking layers BM-1, BM-2 and BM-3 may have a different thickness.

Each of the first to third light blocking layers BM-1, BM-2 and BM-3 may independently include at least one of an acrylic urethane-based compound, an epoxy-based compound, a polyester-based compound, or an epoxy ester-based compound. In one or more embodiments, the first to third light blocking layers BM-1, BM-2 and BM-3 may include the same material or different materials. For example, in one or more embodiments, the first light blocking layer BM-1 and the second light blocking layer BM-2 may include the same material, and the third light blocking layer BM-3 may include a different material from the first light blocking layer BM-1 and the second light blocking layer BM-2. In one or more embodiments, the first light blocking layer BM-1 and the second light blocking layer BM-2 may each include a polyester-based compound, and the third light blocking layer BM-3 may include an epoxy ester-based compound. However, embodiments of the present disclosure are not limited thereto. As the first to third light blocking layers BM-1, BM-2 and BM-3 include one or more of the foregoing materials, high heat resistance may be exhibited even in a deposition process at about 150° C., and thus a crack may not be initiated and excellent or suitable chrominance (ΔE) may be exhibited.

In one or more embodiments, the light blocking layer BM may be formed through one or more suitable deposition methods. For example, in one or more embodiments, the light blocking layer BM may be formed on the bottom surface B-LF of the base layer BL through an electron-beam deposition process. In the electron-beam deposition process for forming the light blocking layer BM, a temperature of a deposition chamber may be about 150° C. In one or more embodiments of the disclosure, as the light blocking layer BM having a multilayer structure has the foregoing thickness range, and includes at least one of an acrylic urethane-based compound, an epoxy-based compound, a polyester-based compound, or an epoxy ester-based compound, the light blocking layer BM may exhibit an excellent or suitable adhesion (measured according to the standard of ASTM D3359) of about 4B or more, and each of chrominances (ΔE) before and after a manufacture process may be about 0.5 or less, and thus the excellent or suitable effect of preventing or reducing light leakage may be provided.

The display device according to one or more embodiments may be applied to one or more suitable electronic devices. An electronic device according to one or more embodiments may include the foregoing display device, and may further include a module or device having other additional function in addition to the display device. In the present disclosure, the term “electronic apparatus” is used interchangeably with the term “electronic device.”

FIG. 6 is a block diagram of an electronic device according to one or more embodiments of the present disclosure. Referring to FIG. 6, an electronic device 10 according to one or more embodiments may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), or a controller. The memory 13 may store data information desired or required for

operations of the processor 12 and/or the display module 11. When the processor 12 executes an application stored in the memory 13, an image data signal and/or an input control signal may be transmitted to the display module 11, and the display module 11 may process the provided signal and output image information through a display screen.

The power module 14 may include a power supply module such as a power adapter or a battery device, and a power conversion module which converts power supplied by the power supply module and generates power desired or required for an operation of the electronic device 10.

At least one of the components of the electronic device 10 described above may be included in the display device according to one or more embodiments described above. In addition, some of individual modules included as functional in one module may be included in the display device, and others may be provided separately from the display device. For example, in one or more embodiments, the display device may include the display module 11, and the processor 12, the memory 13, and the power module 14 may be provided not in the display device but in another type (kind) of device in the electronic device 10.

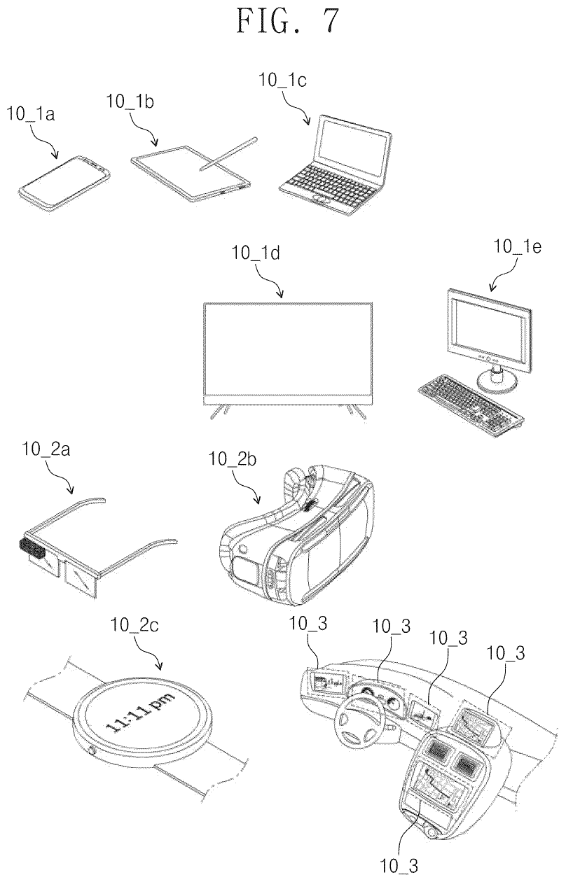

FIG. 7 illustrates schematic views of electronic devices according to one or more embodiments of the present disclosure.

Referring to FIG. 7, one or more electronic devices to which the display device according to one or more embodiments is applied may include not only electronic devices for displaying images, e.g., a smartphone 10_1a, a tablet computer (PC) 10_1b, a laptop computer 10_1c, TV 10_1d, and a monitor for a desk computer 10_1e, but also wearable electronic devices including display modules, e.g., smart glasses 10_2a, a head mounted display 10_2b, and a smart watch 10_2c, and vehicle electronic devices 10_3 including display modules, e.g., a vehicle instrument panel, a center fascia, a center information display (CID) arranged on a dashboard, and a room mirror display.

Referring to 1B, 3, and 4A to 4D together, in an embodiment in which, like the display device DD according to one or more embodiments, the anti-reflective layer 300 included in the display module DM includes the plurality of color filters 320, display efficiency may be improved but the reflectance may be increased compared to a typical display device including a polarizing layer. In a display device not including a polarizing layer, in a black state, a b* color value tends to be excessively shifted in a negative (−) direction. Thus, in addition to a reflection reduction effect, the display device may require a structure of a window to be designed such that the b* color value is close to a center value 0. In the display device DD according to one or more embodiments of the disclosure, as the window WM includes the first layer L1 and the second layer L2, which are arranged adjacent to the upper portion and the lower portion of the base layer BL, respectively, and include the material having a low refractive index, the surface reflectance of the window WM may be decreased. Accordingly, even though the anti-reflective layer 300 of the display module DM includes the plurality of color filters 320, the overall refractive index of the display device DD may be maintained to be low.

Tables 1 and 2 show comparison of physical properties between windows of Comparative Examples and Example. Table 1 shows components of each of the windows of Comparative Examples and Example. The window of Example in Table 1 has the stack structure illustrated in FIG. 4B.

TABLE 1

| Category | Stack Structure of Window |
|---|---|
| Comparative | Base layer (50 μm)/Hard coating layer (5 μm)/ZrO(110 |
| Example 1 | nm)/SiO₂(80 nm)/AF(20-30 nm) |
| Comparative | Base layer (50 μm)/Hard coating layer (5 μm)/Nb₂O₅(11 |
| Example 2 | nm)/SiO₂(25 nm)/Nb₂O₅(105 nm)/SiO₂(68 nm)/ |
| | AF(20-30 nm) |
| Example | MgF₂YOFMgO(75 nm)/Base layer (50 μm)/Hard coating |
| | layer (5 μm)/MgF₂YOFMgO(75 nm)/Si₉Al₂O₁₀(15 nm)/ |
| | AF(35 nm) |

Table 2 shows evaluation of optical characteristics and mechanical characteristics of each of Comparative Examples and Example. In Table 2, reflectances were measured at a wavelength of about 550 nm in a specular component included (SCI) mode by using equipment CM-3700A (by KONICA MINOLTA). Reflective colors were obtained by measuring a color shift value of each of a* and b* in a chromaticity coordinate at the wavelength of about 550 nm, based on the specular component included SCI reflection by using equipment CM-3700A (by KONICA MINOLTA). Each of values a* and b* in the chromaticity coordinate may have a value in a positive (+) direction and a value in a negative (−) direction on the basis of value 0. The value of a* in the positive (+) direction is represented by a red color, and the value of a* in the negative (−) direction is represented by a green color. Also, the value of b* in the positive (+) direction is represented by a yellow color, and the value of b* in the negative (−) direction is represented by a blue color.

A crack strain indicates a level of increase in size of a post-tensioned test sample with respect to the original test sample when tension is applied to the test sample. The test sample at the time of the measurement of the crack strain was prepared by cutting into a size of about 1.0 cm×about 10 cm through laser cutting. A tension speed was about 10 millimeters per minute (mm/min), and after applying tension, whether or not a crack initiated was observed with a microscope, and in this case, the levels of increases in size of the samples were checked and evaluated.

Abrasion resistance may be referred to as rubber abrasion resistance. The abrasion resistance was evaluated by observing, with the naked eyes, a surface after an abrasion test is performed with a rubber stick, or measuring a water contact angle of the surface. The windows to be evaluated were each cut into 7 cm×8 cm and fixed to a jig of a wear resistance meter (scratch tester by DAESUNG Precision Co., Ltd.), and a rubber stick (by Minoan Co., Ltd.) having a diameter of 6 mm was mounted and fixed to a tip. The rubber stick reciprocated and rubbed the surface of the anti-fingerprint layer of the window for test by setting a moving distance to 15 mm, a moving speed to 50 rpm, and a load as 1.0 kg, and then the surface of the rubber stick was observed with the naked eyes, or the water contact angle of the worn surface after the reciprocating friction was measured according to the method for measuring the water contact angle.

TABLE 2

| | | Comparative | Comparative | |
|---|---|---|---|---|
| | | Example 1 | Example 2 | Example |
| Crack strain (%) | | 4.5 | 2.0 | 10.5 |
| Surface reflectance (%) | | 5.0 or less | 5.0 or less | 5.0 or less |
| Reflective color (a*, b*) | | (7.91, −12.9) | (3.5, −9.0) | (0.72, −2.75) |
| Abrasion | Number of | 4000 | 4000 | 10000 |
| resistance | times | | | |
| | Water contact | >95° | >95° | >95° |
| | angle (°) | | | |

Referring to Tables 1 and 2, a thin-film anti-reflective film (AF) having a multilayer structure, in which a low-refractive index thin film and a high-refractive index thin film are alternately stacked, may be used in order to achieve a low reflective characteristic of the display device. It may be confirmed that each of the windows of Comparative Examples 1 and 2 had high effects of reducing the reflectance, but a value b* in a chromaticity coordinate was excessively shifted in the negative (−) direction compared to Example. It may be also confirmed that the windows of Comparative Examples 1 and 2 showed low crack strain values of about 4.5% and about 2.0%, respectively. Compared to the windows of Comparative Examples, in the window of Example, it may be confirmed that in addition to the effects of reducing the reflectance, the value b* in the chromaticity coordinate was shifted in a positive (+), and also the window showed high crack strain values of about 10.5%. Accordingly, it may be confirmed that the window of Example exhibited improved mechanical characteristics compared to the windows of Comparative Examples. For example, it may be confirmed that the window of Example exhibits excellent or suitable optical characteristics, and exhibits excellent or suitable mechanical durability. In the window WM according to one or more embodiments of the disclosure, the first layer L1 and the second layer L2 which are arranged adjacent to the upper portion and the lower portion of the base layer BL, respectively, each include magnesium oxide (e.g., MgO), magnesium fluoride (e.g., MgF₂), and yttrium oxyfluoride (e.g., YOF). As the window WM according to one or more embodiments includes the first layer L1 and the second layer L2 which are arranged adjacent to the upper portion and the lower portion of the base layer BL, respectively, the low-reflection characteristics may be secured, and the abrasion resistance characteristic and the mechanical strength may be improved. Accordingly, reliability and durability of the display device DD including the window WM may be improved.

Table 3 shows results of evaluating window characteristics in accordance with thicknesses of the first layer and the second layer included in the window according to one or more embodiments. The surface reflectance, the reflective color, and the crack strain were evaluated on each of windows of Examples. In Table 3, the windows of Examples are windows each including a stack structure illustrated in FIG. 4A. For example, the windows of Examples are each a window having a structure in which a first layer, a third layer, and a fourth layer are stacked in sequence above a base layer, and a second layer and a light blocking layer are arranged below the base layer. The windows of Examples were each manufactured by changing the thicknesses of the first layer and the second layers. The windows of Examples have substantially the same configuration except the thicknesses of the first layer and the second layers. Example 1 corresponds to an embodiment in which the thickness of each of the first layer and the second layers is about 50 nm. Example 2 corresponds to an embodiment in which the thickness of each of the first layer and the second layers is about 65 nm. Example 3 corresponds to an embodiment in which the thickness of each of the first layer and the second layers is about 75 nm. Example 4 corresponds to an embodiment in which the thickness of each of the first layer and the second layers is about 85 nm. Example 5 corresponds to an embodiment in which the thickness of each of the first layer and the second layers is about 100 nm.

TABLE 3

| | Thickness of | Thickness of | Surface | Reflective color | | Crack |
|---|---|---|---|---|---|---|
| | first layer | second layer | reflectance | (SCI) | | strain |
| Category | (nm) | (nm) | (SCI) | a* | b* | (%) |
| Example 1 | 50 | 50 | 4.26 | −0.26 | −0.92 | 12.5 |
| Example 2 | 65 | 65 | 4.16 | −0.11 | −0.62 | 11.5 |
| Example 3 | 75 | 75 | 4.07 | −0.55 | −2.40 | 10.5 |
| Example 4 | 85 | 85 | 3.51 | −0.08 | −0.46 | 10.0 |
| Example 5 | 100 | 100 | 3.47 | −0.1 | −0.83 | 7 |

Referring to Table 3, in the window of Examples 1 to 5, the surface reflectances were measured to be about 5% or less, and the crack strain values were measured to be about 7% or more. A comparison of Examples 1 to 5 may confirm that, as the thicknesses of the first layer and the second layers were decreased, the crack strain values were increased but the reflectances were increased. It may be also confirmed that, as the thicknesses of the first layer and the second layers were increased, the reflectances were decreased but the crack strain values were decreased. For example, it may be confirmed that the thicknesses of the first layer and the second layers affect the overall reflectance and mechanical physical properties of the window. For example, Table 3 shows that in the windows of Examples 1 to 5, surface reflectances were measured to be about 5% or less, and crack strain values were measured to be about 7% or more. The comparison of Examples 1 to 5 indicates that as the thicknesses of the first and second layers decreased, crack strain values increased while reflectances also increased. Conversely, as the thicknesses of the first and second layers increased, reflectances decreased while crack strain values decreased. This confirms that the thicknesses of the first and second layers affect the overall reflectance and mechanical properties of the window.

The window of Example 1 corresponds to a window provided such that each of the first layer and the second layers had a smaller thickness than those of the windows of Examples 2 to 4. In comparison between Example 1 and Examples 2 to 4, it may be confirmed that, when the thicknesses of the first layer and the second layers were decreased, the mechanical physical properties of the window were improved, but if (e.g., when) the thicknesses passed certain ranges, the reflectance characteristics were decreased. It may be seen that, in the case in which the thickness of each of the first layer and the second layers is less than about 65 nm like Example 1, the surface reflectance may exceed about 4.2%.

The window of Example 5 corresponds to a window provided such that each of the first layer and the second layers had a larger thickness than those of the windows of Examples 2 to 4. In comparison between Example 5 and Examples 2 to 4, it may be confirmed that, when the thicknesses of the first layer and the second layers were increased, the surface reflectance of the window was decreased, but the mechanical characteristics were decreased. It may be seen that, in the case in which the thickness of each of the first layer and the second layers is more than about 85 nm like Example 5, the crack strain value may be decreased to less than about 10%.

It may be confirmed that Examples 2 to 4 each showed higher crack strain value of about 10% or more and also exhibited lower surface reflectance of about 4.2% or less compared to Examples 1 and 5. Thus, it may be confirmed that, in embodiments in which each of the first layer and the second layer satisfies the thickness range of about 65 nm to about 85 nm, the window according to one or more embodiments has excellent or suitable anti-reflection characteristics and excellent or suitable mechanical characteristics.

Windows of display devices may be desired or required to exhibit excellent or suitable mechanical physical properties, which may protect the display devices from external stimuli, and also low-reflection characteristics which may minimize or reduce reflection of light incident from the outside of the display devices. For example, as a window arranged on an upper portion of a display device may be intentionally brought into external contact, the window is highly likely to be scratched or worn and thus may be desired or required to have high resistance to external impact, and/or the like. However, both (e.g., simultaneously) the mechanical physical properties and the optical physical properties desired or required for the windows of the display devices are very difficult to satisfy. The window according to one or more embodiments of the disclosure may include the first layer L1 and the second layer L2, which are arranged respectively above and below the base layer BL, by adjusting the respective thicknesses the first layer L1 and the second layer L2 to the specified ranges, the excellent or suitable optical characteristics are maintained, and the high mechanical physical properties are exhibited. Accordingly, if (e.g., when) the window W, WM-1, WM-2, or WM-3 according to one or more embodiments is applied to the display device, the reliability and durability of the display device may be improved.

According to one or more embodiments of the disclosure, the window may include the first layer and the second layer, which are arranged respectively above and below the base layer and have low refractive indexes, thereby maintaining the excellent or suitable optical characteristics and also exhibiting the high mechanical physical properties. Accordingly, the durability and the reliability of the display device including the window may be improved.

In the present disclosure, expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” “approximately,” or similar terms are used as terms of approximation and not as terms of degree, and are intended to account for the inherent deviations in measured or calculated values that would be recognized by those of ordinary skill in the art. “About” or “approximately” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” or “approximately” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The window-manufacturing apparatus, the light-emitting element, the display module, the display device, the electronic devices/apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although example embodiments of the present disclosure have been described, it is understood that the present disclosure should not be limited to these embodiments but one or more suitable changes and modifications can be made by one ordinary skilled in the art within the spirit and scope of the disclosure as hereinafter claimed. Therefore, the technical scope of the present disclosure is not limited to the contents described in the detailed description of the specification, but should be determined by the appended claims and equivalents thereof.

What is claimed is:

1. A window comprising:
a base layer;
a first layer on the base layer;
a second layer below the base layer;
a third layer on the first layer; and
a fourth layer on the third layer,
wherein each of the first layer and the second layer comprises a magnesium oxide, a magnesium fluoride, and an yttrium oxyfluoride.

2. The window of claim 1, wherein each of the first layer and the second layer has a thickness of about 65 nm to about 85 nm.

3. The window of claim 1, wherein the first layer is in contact with a top surface of the base layer, and
the second layer is in contact with a bottom surface of the base layer.

4. The window of claim 1, wherein a refractive index of each of the first layer and the second layer at a wavelength of about 550 nm is about 1.38 to about 1.42,
a refractive index of the third layer at the wavelength of about 550 nm is about 1.46 to about 1.50, and
a refractive index of the fourth layer at the wavelength of about 550 nm is about 1.30 to about 1.35.

5. The window of claim 1, wherein each of the first layer and the second layer comprises a solid solution in which the magnesium oxide, the magnesium fluoride, and the yttrium oxyfluoride are mixed.

6. The window of claim 1, wherein at least one of the first layer or the second layer further comprises SiₓO_{y}Mg_{z}AlᵤNᵥ, and
wherein, in SiₓO_{y}Mg_{z}AlᵤNᵥ, x, y, z, u, and v are each independently a value of 0 to 1, at least two selected from among x, y, z, u, and v are each independently more than 0 and 1 or less, and satisfy x+y+z+u+v≤1.

7. The window of claim 1, wherein the third layer comprises a silicon oxide and an aluminum oxide.

8. The window of claim 1, wherein the third layer comprises Si₉Al₂O₁₀.

9. The window of claim 1, wherein the fourth layer comprises a fluorine-containing polymer.

10. The window of claim 1, wherein a reflectance of a top surface of the fourth layer at a wavelength of about 550 nm is about 4.2% or less.

11. The window of claim 1, further comprising a fifth layer between the base layer and the first layer and comprising a hard coating agent, wherein the first layer is directly on the fifth layer.

12. The window of claim 1, wherein the third layer has a thickness of about 5 nm to about 30 nm, and
the fourth layer has a thickness of about 5 nm to about 40 nm.

13. The window of claim 1, wherein the base layer is divided into a transmission area and a bezel area on a plane, and
wherein the window further comprises a light blocking layer below the base layer and overlapping the bezel area.

14. The window of claim 13, wherein the base layer comprises a top surface adjacent to the first layer and a bottom surface opposing the top surface in a thickness direction,
wherein each of the light blocking layer and the second layer is on the bottom surface of the base layer, and
wherein the light blocking layer does not overlap the second layer in a plan view.

15. The window of claim 13, wherein the second layer overlaps the transmission area and the bezel area, and
the light blocking layer is on a bottom surface of the second layer.

16. The window of claim 13, wherein the light blocking layer comprises:
a first light blocking layer below the base layer; and
a second light blocking layer below the first light blocking layer, and
wherein each of the first light blocking layer and the second light blocking layer comprises at least one of an acrylic urethane-based compound, an epoxy-based compound, a polyester-based compound, or an epoxy ester-based compound.

17. A display device comprising:
a display module; and
a window on the display module,
wherein the window comprises:
a base layer;
a first layer on the base layer;
a second layer below the base layer;
a third layer on the first layer; and
a fourth layer on the third layer,
wherein each of the first layer and the second layer comprises a magnesium oxide, a magnesium fluoride, and an yttrium oxyfluoride.

18. The display device of claim 17, wherein the display module comprises:
a base substrate;
a circuit layer on the base substrate;
a light emitting element layer on the circuit layer, the light emitting element layer comprising a plurality of light emitting elements;
an encapsulation layer on the light emitting element layer; and
an anti-reflective layer on the encapsulation layer, the anti-reflective layer comprising:
a division layer in which a plurality of division openings overlapping the plurality of light emitting elements, respectively, are defined; and
a plurality of color filters arranged to correspond to the plurality of division openings, respectively.

19. The display device of claim 17, wherein the base layer is spaced from the display module with the second layer therebetween, and
wherein a top surface of the fourth layer defines an outermost surface of the window.

20. An electronic device providing an image,
the electronic device comprising:
a display module;
a window on the display module; and
a housing below the display module and coupled with the window to accommodate the display module,
wherein the window comprises:
a base layer;
a first layer on the base layer;
a second layer below the base layer;
a third layer on the first layer; and
a fourth layer on the third layer,
wherein each of the first layer and the second layer comprises a magnesium oxide, a magnesium fluoride, and an yttrium oxyfluoride.
